(19) United States
(12) Patent Application Publication
(10) Pub. No.: US 2008/0175079 A1
(43) Pub. Date: Jul. 24, 2008

(54) Test scheme for fuse circuit

(75) Inventors: Soon-Keun Jeon, Suwon-si (KR); Se-Hyun Hwang, Suwon-si (KR); Suk-Soo Pyo, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/008,468

(22) Filed: Jan. 11, 2008

(30) Foreign Application Priority Data
Jan. 17, 2007 (KR) 10-2007-0005261

(51) Int. Cl. G11C 29/00; G11C 7/00; G11C 17/18

(52) U.S. Cl. 365/200; 365/225.7; 365/201

(57) ABSTRACT

Provided is an apparatus and a method for testing an electrical fuse. In accordance therewith: a first test is performed on a plurality of memory cells arranged with a plurality of rows and a plurality of columns; a line related to a defective cell is repaired with a redundant line by using an electrical fuse; data outputted from the redundant line is set with a predetermined value; performing a second test on the plurality of memory cells; and a determination is made of whether or not data outputted from the line related to a defective cell has the predetermined value.

### CROSS-REFERENCE TO RELATED APPLICATIONS

This U.S. non-provisional patent application claims priority under 35 U.S.C. § 119 to Korean Patent Application No. 10-2007-0005261, filed in the Korean Intellectual Property Office on Jan. 17, 2007, the entire contents of which are hereby incorporated by reference.

### FIELD OF THE INVENTION

The present invention disclosed herein relates to a semiconductor memory device, and more particularly, to a device for detecting a fusing error in a semiconductor memory device.

### BACKGROUND

A semiconductor memory device stores and reads data, as necessary. The semiconductor memory device is largely classified into a random access memory (RAM) and a read only memory (ROM). RAM is a volatile memory where stored data disappears when no power is applied. RAM includes dynamic RAM (DRAM), static RAM (SRAM), etc. ROM is a nonvolatile memory where data remains when no power is applied. RAM includes programmable ROM (PROM), erasable ROM (EROM), electrically EPROM (EEPROM), and flash memory devices.

The semiconductor memory device includes a plurality of memory cells in a matrix where word lines and bit lines intersect each other. The semiconductor memory device may not function properly if one memory cell has a defect, among the plurality of memory cells. However, as the degree of integration in the semiconductor memory device increases, the possibility of defect occurrence in the memory cells increases. The memory cell with a defect is a main factor that reduces the yield of the semiconductor memory device. Accordingly, the semiconductor memory device compensates for the defect by replacing a word line (or, a bit line) connected to a defect cell with a spare word line (or, a bit line) when there is a defect in the memory cells. When an address for selecting the defect cell is given, a normal path for accessing the defect cell is cut off and instead of using it, a redundant word line (or, a redundant bit line) connected to a redundant cell is enabled. As a result, a normal access operation can be executed.

Fuse circuits are used to repair a word line (or, a bit line) connected to a defect cell by using a spare word line (or, a bit line). The fuse circuits include a laser fuse circuit using a laser and an electrical programmable fuse circuit, i.e., an e-fuse circuit, using the property of a resistance device according to voltage supply. The e-fuse circuit does not require additional equipment during mode switching or repairing, and a simple algorithm can be used for realizing that redundancy. Therefore, the e-fuse circuit is extensively used.

An operator can easily confirm whether a fuse is blown out or not in the laser fuse circuit through a microscope. However, this may be difficult to do in the e-fuse circuit. Moreover, when malfunctions of an e-fuse circuit occur, it is difficult to know whether the fault lies in a repair analysis program or an electrical fusing algorithm.

### SUMMARY OF THE INVENTION

The present invention provides for improved testing an e-fuse circuit.

In accordance with one aspect of the present invention, provided is a method for testing an electrical fuse. The method includes: performing a first test on a plurality of memory cells arranged with a plurality of rows and a plurality of columns; repairing a line related to a defective cell with a redundant line by using an electrical fuse; setting data outputted from the redundant line with a predetermined value; performing a second test on the plurality of memory cells; and determining whether or not data outputted from the line related to a defective cell has the predetermined value.

The method can further include indicating an electrical fusing algorithm error when the data outputted from the line related to a defective cell does not have the predetermined value.

The method can further include performing a debugging operation on an electrical fusing algorithm when the data outputted from the line related to a defective cell does not have the predetermined value.

The method can further include determining whether or not an address of the line related to a defective cell is identical to an address of the line outputting the predetermined value.

The method can further include indicating an error on a repair analysis program when the address of the line related to a defective cell is not identical to the address of the line outputting the predetermined value.

The method can further include performing a debugging operation when the address of the line related to a defective cell is not identical to the address of the line outputting the predetermined value.

The rows of the memory cells can be connected to word lines, respectively; the columns of the memory cells can be connected to bit lines; and the line related to a defective cell can be one of the word lines and the bit lines.

The method further include stopping the second test when a new defective cell occurs during the performing of the second test on the plurality of memory cells.

The predetermined value of the data outputted from the redundant line can be low level data.

In accordance with another aspect of the present invention, provided is a semiconductor memory device that includes: a plurality of main memory cells connected to a plurality of word lines and a plurality of bit lines; redundant memory cells connected to a plurality of redundant bit lines; an electrically-disconnectable electrical fuse circuit configured to repair a defective bit line connected to a defective main memory with the redundant line in response to an address signal, and to activate a redundant enable signal when the address signal designates the defective bit line during a test mode; and an input/output driver configured to change data outputted from the redundant memory cells into a predetermined value and to output the predetermined value as output data in response to the redundant enable signal during a test mode.

The input/output driver can be configured to output data during a normal mode, the data being outputted from one of the main memory cells and the redundant memory cells.

The electrical fuse circuit can include: a fuse circuit configured to store address information of a defective bit line; and a logic circuit configured to activate the redundant enable signal when address information of at least one defective bit line is stored in the fuse circuit.

The electrical fuse circuit can include: a fuse circuit configured to store address information of the defective bit line and to output a plurality of state signals representing whether the redundant bit lines are connected to the defective bit lines, respectively; and a logic circuit configured to receive the state signals, and to output the redundant enable signal.

The input/output driver can include a redundant output enforcing circuit configured to change the data outputted from the redundant memory cells into the predetermined value and to output the predetermined value as the output data when the redundant enable signal is activated.

The redundant output enforcing circuit can include: a delivery gate circuit configured to deliver the data outputted from the redundant memory cells into an output node while the redundant enable signal is not activated; and a first circuit configured to deliver a power voltage to the output node while the redundant enable signal is activated. The output data is outputted through the output node.

In further embodiments, the redundant output enforcing circuit can further include a latch circuit configured to latch a signal level of the output node while the redundant enable signal is activated.

The delivery gate circuit can include: a first control signal generating circuit configured to generate a first control signal in response to a clock signal and the redundant enable signal; an inverter configured to receive the first control signal and to output an inverted control signal; and a transmission gate configured to deliver data from the redundant memory cells into the output node in response to the first control signal and the inverted control signal.

The first circuit can include: a second control signal generating circuit configured to generate a second control signal in response to a reset signal and the redundant enable signal; and a transistor connected between the power voltage and the output node and controlled by the second control signal.

In accordance with still another aspect of the present invention, provided is a semiconductor memory device that includes: a plurality of main memory cells connected to a plurality of word lines and a plurality of bit lines; redundant memory cells connected to a plurality of redundant bit lines; an electrically-disconnectable electrical fuse circuit configured to repair a defective word line connected to a defective main memory with the redundant line in response to an address signal, and to activate a redundant enable signal when the address signal designates the defective word line during a test mode; and an input/output driver configured to change data outputted from the redundant memory cells into a predetermined value and to output the predetermined value as output data in response to the redundant enable signal during the test mode.

The input/output driver can be configured to output data during a normal mode, the data being outputted from one of the main memory cells and the redundant memory cells.

The electrical fuse circuit can include: a fuse circuit configured to store address information of a defective bit line; and a logic circuit configured to activate the redundant enable signal when address information of at least one defective bit line is stored in the fuse circuit.

The electrical fuse circuit can include: a fuse circuit configured to store address information of the defective bit line and outputting a plurality of state signals representing whether the redundant bit lines are connected to the defective bit lines, respectively; and a logic circuit configured to receive the state signals, and to output the redundant enable signal.

In accordance with even another aspect of the present invention, test system includes: a semiconductor memory device; and a test device configured to provide an address signal, a data signal, control signals, and a test signal to the semiconductor memory device and to test the semiconductor memory device. The semiconductor memory device includes: a plurality of main memory cells connected to a plurality of word lines and a plurality of bit lines; redundant memory cells connected to a plurality of redundant bit lines; and an electrically-disconnectable electrical fuse circuit configured to repair a defective bit line connected to a defective main memory with the redundant line in response to an address signal, and to activate a redundant enable signal when at least one bit line is repaired.

The test device can include an input/output driver configured to change data outputted from the redundant memory cells into a predetermined value and to output the predetermined value as output data in response to the redundant enable signal during a test mode.

### BRIEF DESCRIPTION OF THE FIGURES

The accompanying figures are included to provide a further understanding of aspects of the present invention, and are incorporated in and constitute a part of this specification. The drawings illustrate exemplary embodiments in accordance with the present invention and, together with the description, serve to explain principles of the present invention. In the figures:

FIG. 1 is a block diagram of an embodiment of a test system according to an aspect of the present invention;

FIG. 2 is a block diagram of an embodiment of a structure of a memory device of FIG. 1;

FIG. 3 is a circuit diagram of an embodiment of an electrical fuse circuit of FIG. 2;

FIG. 4 is a circuit diagram of an embodiment of a structure related to a data output of an input/output driver of FIG. 2; and

FIGS. 5A and 5B are flowcharts of an embodiment of a method for testing a semiconductor memory device according to an aspect of the present invention.

### DETAILED DESCRIPTION OF PREFERRED EMBODIMENTS

Hereinafter, exemplary embodiments in accordance with the present invention will be described with the accompanying drawings. While describing these embodiments, detailed descriptions of well-known items, functions, or configurations are typically omitted for conciseness.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

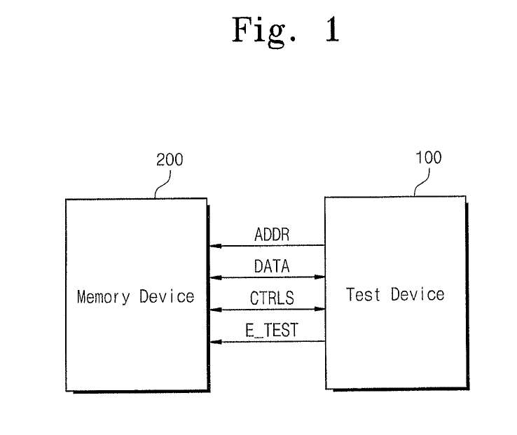

FIG. 1 is a block diagram of an embodiment of a test system according to an aspect of the present invention. Referring to FIG. 1, the test system includes a memory device 200 and a test device 100 for testing the memory device 200. The test device 100 provides an address signal ADDR, a data signal DATA, control signals CTRLS, and a test mode signal E_TEST to the memory device 200, and determines whether the memory device 200 has a defect or not based on the data signal DATA outputted from the memory device 200. The memory device 200 can be applied to any memory device with a redundancy structure, such as electrically EPROM (EEPROM), a flash memory, etc.

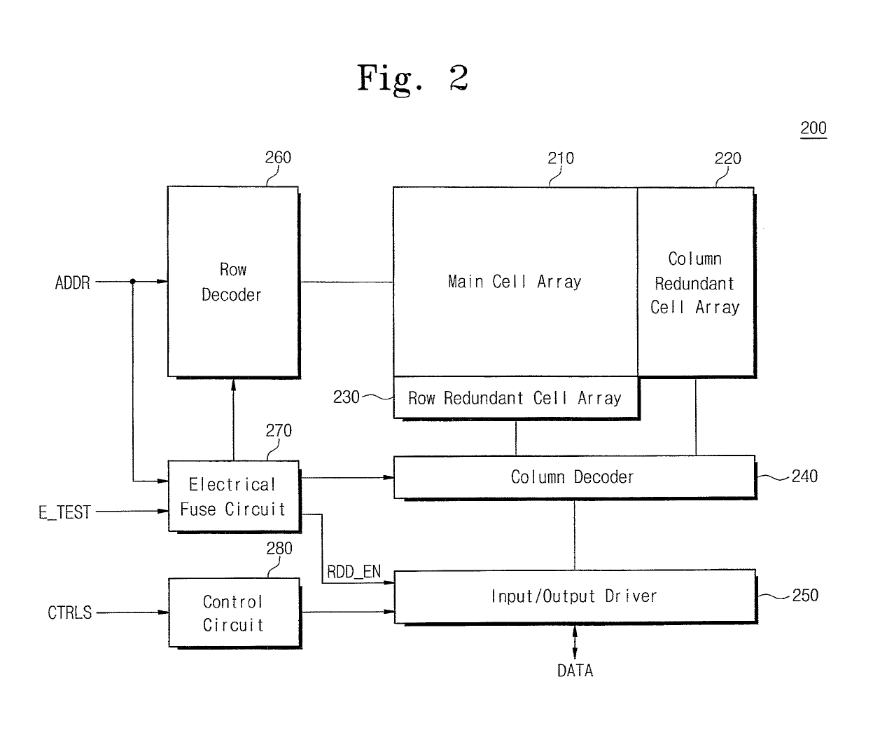

FIG. 2 is a block diagram of an embodiment of a structure of a memory device of FIG. 1. Referring to FIG. 2, the memory device 200 includes a main cell array 210, a column redundant cell array 220, a row redundant cell array 230, a column decoder 240, an input/output driver 250, a row decoder 260, an electrical fuse circuit 270, and a control circuit 280.

The main cell array 210 includes a plurality of memory cells configured to store main data. A plurality of rows (or, main word lines) and a plurality of columns (or, main bit lines) are arranged in the main memory cell array 210. The column redundant cell array 220 includes a plurality of memory cells configured to replace a defective column(s) of the main cell array 210, and the row redundant cell array 230 includes a plurality of memory cells configured to replace a defective row(s) of the main cell array 210. As well-known, the column redundant cell array 220 and the row redundant cell array 230 have a structure identical to that of the main cell array 210.

The electrical fuse circuit 270 stores a defective row address and/or a defective column address of the main cell array 210. The electrical fuse circuit 270 controls the row decoder 260 and/or the column decoder 270 to select the row redundant cell array 230 and/or the column redundant cell array 220 when the address signal ADDR inputted from the test device 100 of FIG. 1 is identical to the stored defect row address and/or defect column address.

The memory device of FIG. 2 includes the column redundant cell array 220 and the row redundant cell array 230, but other memory devices include one of the column redundant cell array 220 and the row redundant cell array 230.

The electrical fuse circuit 270 activates the redundant enable signal RDD_EN when any one of the defective row address and/or the defective column address stored therein is identical to the address signal ADDR inputted from the test device 100 while the test mode signal E_TEST is activated. The redundant enable signal RDD_EN is applied to the input/output driver 250.

The row decoder 260 generates a row select signal to select one of the word lines of the main cell array 210 and the row redundant cell array 230 in response to a row address among the address signals ADDR.

The column decoder 240 generates a column select signal to select one of the bit line lines of the main cell array 210 and the column redundant cell array 220 in response to a column address among the address signals ADDR inputted through the electrical fuse circuit 270.

The control circuit 280 controls general operations of the memory device 200 in response to the control signals CTRLS and the test mode signal inputted from the test device 100 of FIG. 1.

The input/output driver 250 outputs a fail data signal of a predetermined level into the test device 100 as the output data signal DATA instead of a data signal outputted from the column redundant cell array 220 through the column decoder 240 while the redundant enable signal RDD_EN is activated. For example, the output data signal DATA outputted from the column redundant cell array 220 is in a low level while the redundant enable signal RDD_EN is activated.

To test the memory device 200 with the above structure, the test device 100 tests whether the main cell array 210 is defective or not in a first test stage, and then programs the address information of a line related to a defective cell, i.e., a defective bit line or a defective word line, into the electrical fuse circuit 270.

The test device 100 activates the test mode signal E_TEST and tests a line having a defective cell, i.e., a defective bit line or a defective word line, in a second test operation. The electrical fuse circuit 270 of the memory device 200 activates the redundant enable signal RDD_EN when the address signal ADDR is identical to the address information of a defective bit line or a defective word line stored in the electrical fuse circuit 270. The input/output driver 250 sets the output data DATA in a low level when the redundant enable signal RDD_EN is activated.

The test device 100 of FIG. 1 determines whether or not the electrical fuse circuit 270 is normally fused when all the data signal DATA are in a low level, which are outputted from the line related to a defective cell of the memory device 200, i.e., a defective bit line or a defective word line. A fusing state of the e-fuse can be tested by using the test scheme.

Additionally, the test device 100 can further include a storage circuit (not shown) for storing a fail bit map. A memory device designer confirms the fail bit map to determine whether or not defective cells in the main cell array 210 are accurately repaired with the column redundant cell array 220 or the row redundant cell array 230. If a normal cell, not the defective cell, is repaired with the column redundant cell array 220 or the row redundant cell array 230, debugging is required for a repair analysis program of the test device 100.

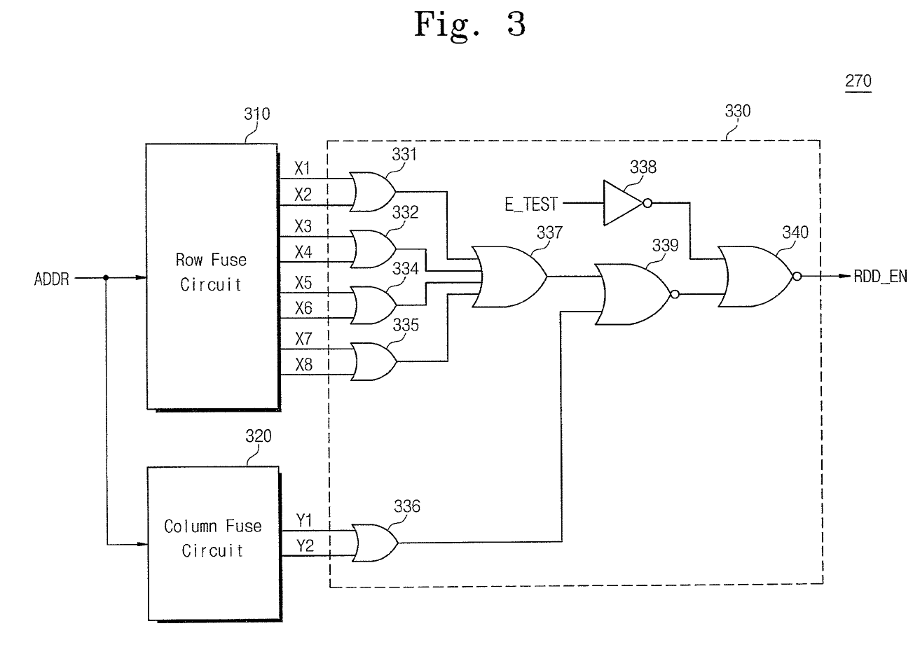

FIG. 3 is an embodiment of a circuit diagram of an electrical fuse circuit of FIG. 2.

Referring to FIG. 3, the electrical fuse circuit 270 includes a row fuse circuit 310, a column fuse circuit 320, and a logic circuit 330. The logic circuit 330 includes OR gates 3311 to 337, an inverter 338, and NOR gates 339 and 340.

The row fuse circuit 310 stores the address information of a word line connected to a defective cell of the main cell array 210 of FIG. 2. The column fuse circuit 320 stores the address information of a bit line connected to a detective cell of the main cell array 210 of FIG. 2. Each of the row fuse circuit 310 and the column fuse circuit 320 includes an e-fuse circuit.

The row fuse circuit 310 of FIG. 3 can store the address information of 8 defective word lines at most, and outputs redundant word line select signals X1 to X8 corresponding to the respective defective word lines. The row fuse circuit 310 compares the address information of the stored defective word lines with the address signal ADDR inputted from the test device 100, and activates a redundant word line select signal corresponding to a defective word line address identical to the inputted address signal ADDR.

The column fuse circuit 320 can store the address information of 2 defective bit lines at most and outputs redundant bit line select signals Y1 and Y2 corresponding to the respective defective bit lines. The column fuse circuit 320 compares the address information of the stored defective bit lines with the address signal ADDR inputted from the test device 100, and activates a redundant bit line select signal corresponding to the defective bit line address identical to the inputted address signal ADDR.

The NOR gate 339 outputs a signal of a low level when at least one of the redundant word line select signals X1 to X8 and the redundant bit line select signals Y1 and Y2 is activated in a high level. The NOR gate 340 activates the redundant enable signal RDD_EN in a high level when the test mode signal E_TEST is activated in a high level and an output of the NOR gate 339 is in a low level.

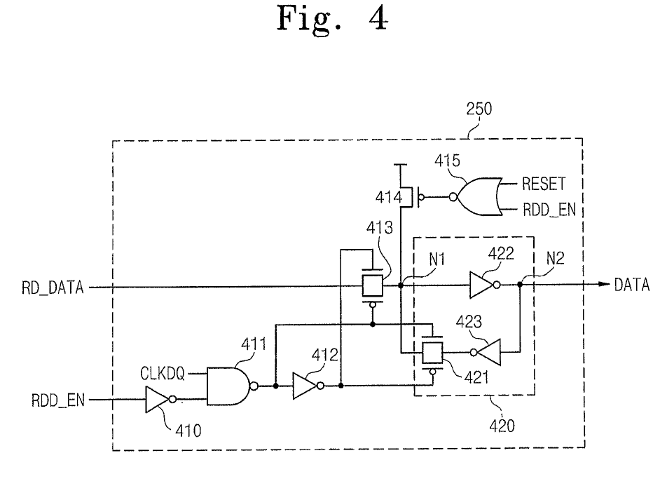

FIG. 4 is a circuit diagram of an embodiment of a structure related to a data output of the input/output driver of FIG. 2.

Referring to FIG. 4, the input/output driver 250 includes inverters 410 and 412, a NAND gate 411, a transmission gate 413, a PMOS transistor 414, a NOR gate 415, and a latch 420.

The inverter 410 receives the redundant enable signal RDD_EN. The NAND gate 411 receives an output of the inverter 410 and a clock signal CLKDQ. The clock signal CLKDQ can be generated by a clock generator (not shown) in the memory device 200. In another example, the clock signal CLKDQ can be provided from the test device 100. The inverter 412 inverts and outputs an output of the NAND gate 411.

The transmission gate 413 outputs read data RD_DATA, which are read from the main cell array 210, the column redundant cell array 220, or the row redundant cell array 230 through the column decoder 240, into a node of FIG. 2 in response to outputs of the NAND gate 411 and the inverter 412.

The NOR gate 415 receives a reset signal RESET and a redundant enable signal RDD_EN inputted from the control circuit 280. The PMOS transistor 414 is connected between a power voltage and a node N1, and its gate is controlled by an output of the NOR gate 415. In another embodiment, the reset signal RESET can be directly inputted from the test device 100.

The latch 420 includes a transmission gate 421 and inverters 422 and 423. The transmission gate 421 is connected between the nodes N1 and an N2, and is controlled by outputs of the NAND gate 411 and the inverter 412. The inverter 422 is connected between the nodes N1 and N2, and the inverter 423 is connected between the node N2 and an input terminal of the transmission gate 421.

The input/output driver 250 with the above structure outputs read data RD_DATA read from the main cell array 210, the column redundant cell array 220 or the row redundant cell array 230 as the data signal RDD through the column decoder 240 when the redundant enable signal RDD is in a low level. To the contrary, in the input/output driver 250, the transmission gate 413 is turned off and the PMOS transistor 412 is turned on to set the node N1 to be in a high level when the redundant enable signal RDD is in a high level. Therefore, the data signal DATA of a low level, which are inverted by the inverter 422, are outputted. At this point, the transmission gate 421 is turned on to latch a signal level of the nodes N1 and N2.

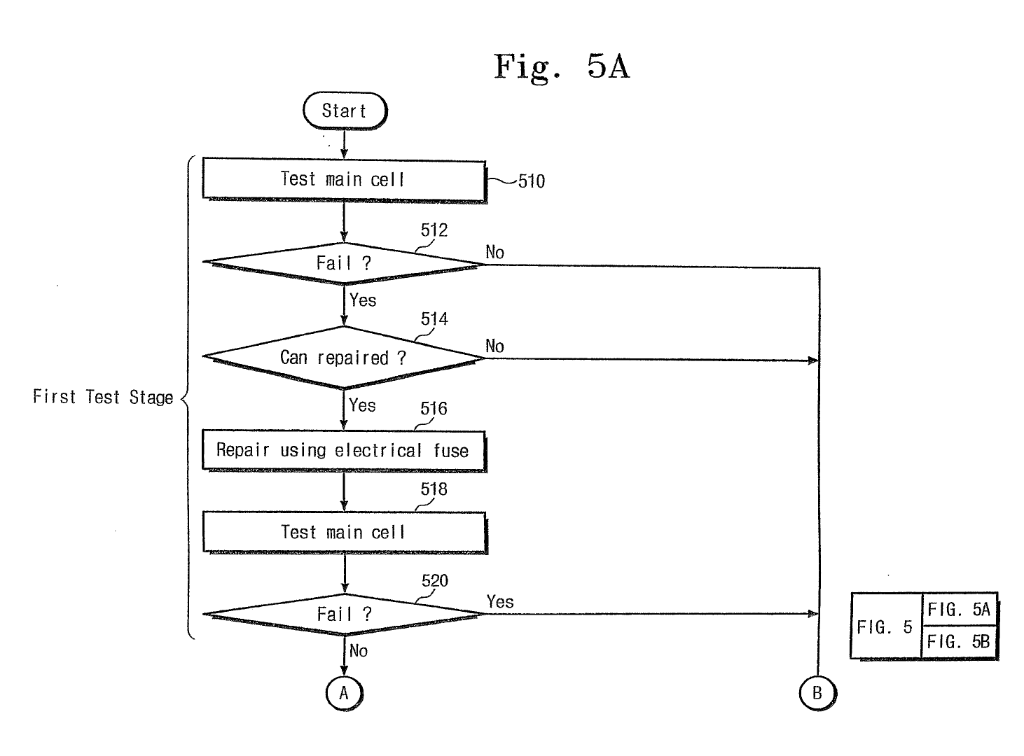

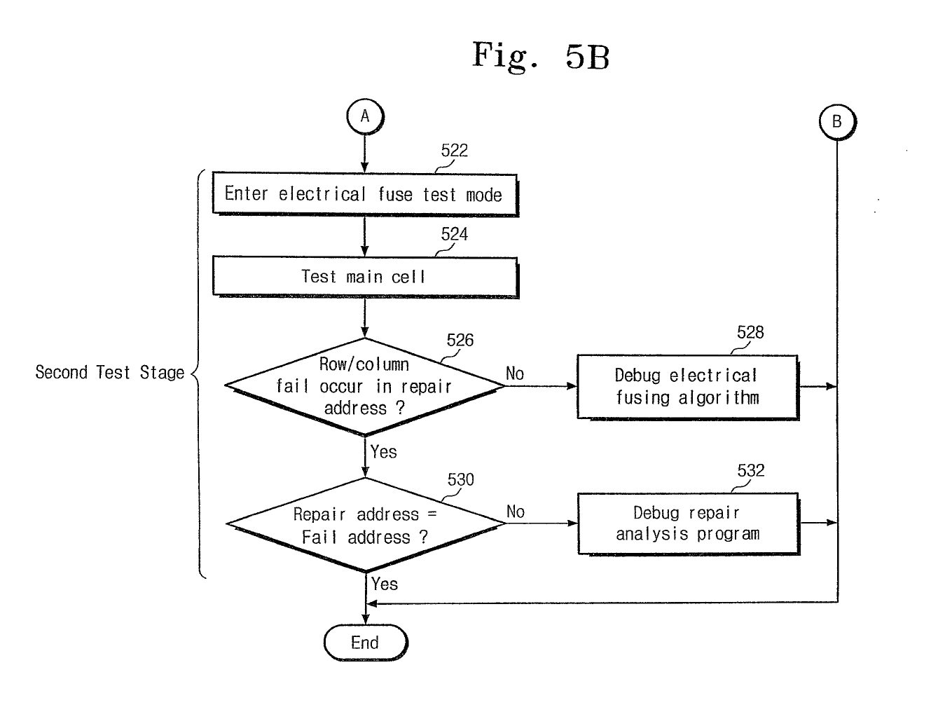

FIGS. 5A and 5B are flowcharts of an embodiment of a method for testing a semiconductor memory device according to an aspect of the present invention.

Referring to FIGS. 5A and 5B, testing of the semiconductor memory device 200 by the test device 100 includes a first test stage and a second test stage. The first test stage includes extracting an appropriate sample for testing whether an e-fuse is normally cut. The second test stage includes testing the e-fuse.

In the first test stage, the test device 100 tests for the main cell array 210 of the semiconductor memory device 200 in operation 510. Generally, the testing of the main cell array 210 includes storing predetermined data in the main cell array 210 and reading the stored data to determine whether a main cell is failed or not according to whether or not the stored data is identical to the read data.

When it is determined whether or not at least one cell with a defect exists in the main cell array 210 in operation 512, a repair analysis program in the test device 100 determines whether the defect of the main cell array 210 can be repaired or not in operation 514. If the defect of the main cell array 210 can be repaired, the main cell array 210 is repaired with the column redundant cell array 220 or the row redundant cell array 230 by using the electric fuse circuit 270 in the memory device 200, in operation 516. Because the scheme for repairing the main cell with the redundant cell is well known, its detailed description will be omitted for conciseness. If the answer in operation 514 were “no,” then the method is terminated via connector “B” to FIG. 5B.

The test device 100 again tests the main cell array 210 of the memory device 200 in operation 518. If there is a defective cell determined in operation 520, if the repairing of the cell using the electrical fuse was performed in operation 516, it is determined that the memory device for test is not an appropriate sample for testing the e-fuse, and the test stops via connector “B” to FIG. 5B. If there is no defective cell, the first stage is completed and the method continues to the second test stage, which is presented in FIG. 5B.

In the second test stage, the test device 210 enters into an electrical fuse test mode in operation 522. In this stage, the test device 210 activates the test mode signal E_TEST with a high level.

The test device 100 performs a test on the semiconductor memory device 200 in operation 524. The electrical fuse circuit 270 of the memory device 200 activates a redundant enable signal RDD_EN when the address signal ADDR inputted from the test device 100 identifies a defective bit line or a defective word line. Therefore, the data signal DATA outputted from the row redundant cell array 230 or the column redundant cell array 220 becomes a low level. This would seem to indicated that a failure occurred in one line, i.e., an entire row/column. That is, in the second test stage, the data signal DATA outputted from the redundant cell array 230 or the column redundant cell array 220 indicates a respective row/column failure.

In operation 526, the test device 100 receives the data signal DATA from the memory device 200, and then determines whether or not the row/column failure occurs in the repaired address (defective word line/bit line address) of the main cell array 210 during the repairing of the cell by the electrical fuse of operation 516. If there is no row/column failure, the test device 100 determines that an error occurred in the electrical fusing algorithm in operation 528. At this point, debugging may be required for the electrical fusing algorithm.

In operation 530, if there is the row/column failure, the test device 100 determines whether or not the address (defect word line/bit line address) repaired during the operation 516 is identical to the address where the actual row/column failure occurred. Whether or not the repaired address is identical to the address where the actual row/column failure occurred can be directly determined by using a fail bit map stored in the test device 100.

When there is a defect in a predetermined cell of a bit line A, the defective bit line A is replaced with a redundant bit line through the operation 516. When the defective bit line A is accessed by the main cell test of the second test state of the operation 524, the redundant bit line is accessed instead of the defective bit line A. Therefore, the data signal DATA outputted from the defective bit line A are all in a low level. That is, it seems as if column failure occur in the bit line A, as is appropriate.

However, if a normal bit line B is replaced with the redundant bit line instead of the defective bit line A having the actual defective cells due to an error of the repair analysis program, it seems as if column failure occurred in the normal bit line B. In this case, debugging is required for the repair analysis program in operation 532.

According to aspects of the present invention, therefore, it is possible to test whether or not fusing of the e-fuse circuit is normal.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor memory device comprising:
a plurality of main memory cells connected to a plurality of word lines and a plurality of bit lines;
redundant memory cells connected to a plurality of redundant bit lines;
an electrically-disconnectable electrical fuse circuit configured to repair a defective bit line connected to a defective main memory with the redundant line in response to an address signal, and to activate a redundant enable signal when the address signal designates the defective bit line during a test mode; and
an input/output driver configured to change data outputted from the redundant memory cells into a predetermined value and to output the predetermined value as output data in response to the redundant enable signal during a test mode.

2. The device of claim 1, wherein the input/output driver is configured to output data during a normal mode, the data being outputted from one of the main memory cells and the redundant memory cells.

3. The device of claim 1, wherein the electrical fuse circuit comprises:
a fuse circuit configured to store address information of a defective bit line; and
a logic circuit configured to activate the redundant enable signal when address information of at least one defective bit line is stored in the fuse circuit.

4. The device of claim 1, wherein the electrical fuse circuit comprises:
a fuse circuit configured to store address information of the defective bit line and to output a plurality of state signals representing whether the redundant bit lines are connected to the defective bit lines, respectively; and
a logic circuit configured to receive the state signals, and to output the redundant enable signal.

5. The device of claim 1, wherein the input/output driver comprises a redundant output configured to enforce circuit changing the data outputted from the redundant memory cells into the predetermined value and to output the predetermined value as the output data when the redundant enable signal is activated.

6. The device of claim 5, wherein the redundant output enforcing circuit comprises:
a delivery gate circuit configured to deliver the data outputted from the redundant memory cells into an output node while the redundant enable signal is not activated; and
a first circuit configured to deliver a power voltage to the output node while the redundant enable signal is activated,
wherein the output data is outputted through the output node.

7. The device of claim 6, wherein the redundant output enforcing circuit further comprises a latch circuit configured to latch a signal level of the output node while the redundant enable signal is activated.

8. The device of claim 6, wherein the delivery gate circuit comprises:
a first control signal generating circuit configured to generate a first control signal in response to a clock signal and the redundant enable signal;
an inverter configured to receive the first control signal and to output an inverted control signal; and
a transmission gate configured to deliver data from the redundant memory cells into the output node in response to the first control signal and the inverted control signal.

9. The device of claim 8, wherein the first circuit comprises:
a second control signal generating circuit configured to generate a second control signal in response to a reset signal and the redundant enable signal; and
a transistor connected between the power voltage and the output node and controlled by the second control signal.

10. A semiconductor memory device comprising:
a plurality of main memory cells connected to a plurality of word lines and a plurality of bit lines;
redundant memory cells connected to a plurality of redundant bit lines;
an electrically-disconnectable electrical fuse circuit configured to repair a defective word line connected to a defective main memory with the redundant line in response to an address signal, and to activate a redundant enable signal when the address signal designates the defective word line during a test mode; and
an input/output driver configured to change data outputted from the redundant memory cells into a predetermined value and to output the predetermined value as output data in response to the redundant enable signal during the test mode.

11. The device of claim 10, wherein the input/output driver is configured to output data during a normal mode, the data being outputted from one of the main memory cells and the redundant memory cells.

12. The device of claim 10, wherein the electrical fuse circuit comprises:
a fuse circuit configured to store address information of a defective bit line; and
a logic circuit configured to activate the redundant enable signal when address information of at least one defective bit line is stored in the fuse circuit.

13. The device of claim 10, wherein the electrical fuse circuit comprises:
a fuse circuit configured to store address information of the defective bit line and to output a plurality of state signals representing whether the redundant bit lines are connected to the defective bit lines, respectively; and
a logic circuit configured to receive the state signals, and to output the redundant enable signal.

14. A test system comprising:
a semiconductor memory device; and
a test device configured to provide an address signal, a data signal, control signals, and a test signal to the semiconductor memory device and to test the semiconductor memory device,
wherein the semiconductor memory device includes:
a plurality of main memory cells connected to a plurality of word lines and a plurality of bit lines;
redundant memory cells connected to a plurality of redundant bit lines; and
an electrically-disconnectable electrical fuse circuit configured to repair a defective bit line connected to a defective main memory with the redundant line in response to an address signal, and to activate a redundant enable signal when at least one bit line is repaired.

15. The test system of claim 14, wherein the test device comprises an input/output driver configured to change data outputted from the redundant memory cells into a predetermined value and to output the predetermined value as output data in response to the redundant enable signal during a test mode.
